(19) United States
(12) Patent Application Publication
(10) Pub. No.: US 2025/0287756 A1
(43) Pub. Date: Sep. 11, 2025

(54) HIGH-SPEED MICRO-LED DEVICE

(71) Applicant: LUMILEDS LLC, San Jose, CA (US)

(72) Inventor: Mark James HOLMES, San Jose, CA (US)

(73) Assignee: LUMILEDS LLC, San Jose, CA (US)

(21) Appl. No.: 19/215,677

(22) Filed: May 22, 2025

Related U.S. Application Data
(63) Continuation of application No. PCT/US2023/081142, filed on Nov. 27, 2023.
(60) Provisional application No. 63/433,138, filed on Dec. 16, 2022.

(51) Int. Cl. H10H 29/851; H01L 25/075; H10H 20/01; H10H 20/825; H10H 29/01; H10H 29/14; H10H 29/85

(52) U.S. Cl. CPC H10H 29/8512; H01L 25/0753; H10H 20/01335; H10H 20/825; H10H 29/0364; H10H 29/142; H10H 29/857

(57) ABSTRACT

An inventive light-emitting array includes multiple semiconductor light-emitting diodes (LEDs). Each LED of the array includes first and second doped semiconductor layers and an active layer them, and emits light at a nominal emission vacuum wavelength λ₀ resulting from charge carrier recombination at the active layer. The active layer differs in chemical composition from the first and second semiconductor layers and is between 0.1 nm thick and 1 nm thick. Each LED exhibits a small-signal bandwidth greater than 0.10 GHZ, in some instances at a nonzero current density less than 2000 A/cm². In some instances the doped semiconductor layers can be p-doped and n-doped GaN layers, and the active layer can be a monolayer of a III-nitride compound, e.g., InGaN.

### PRIORITY CLAIM

This application is a continuation of App. No. PCT/US2023/081142 entitled “High-speed micro-LED device” filed 27 Nov. 2023 in the name of Mark James Holmes, which in turn claims priority of U.S. provisional App. No. 63/433, 138 entitled “High-speed micro-LED device” filed 16 Dec. 2022 in the name of Mark James Holmes, both of said applications being incorporated herein by reference in their entireties.

### FIELD OF THE INVENTION

The invention relates generally to light emitting diodes and to phosphor-converted light emitting diodes.

### BACKGROUND

Semiconductor light emitting diodes and laser diodes (collectively referred to herein as “LEDs”) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths.

LEDs may be combined with one or more wavelength converting materials (generally referred to herein as “phosphors”) that absorb light emitted by the LED and in response emit light of a longer wavelength. For such phosphor-converted LEDs (“pcLEDs”), the fraction of the light emitted by the LED that is absorbed by the phosphors depends on the amount of phosphor material in the optical path of the light emitted by the LED, for example on the concentration of phosphor material in a phosphor layer disposed on or around the LED and the thickness of the layer.

Phosphor-converted LEDs may be designed so that all of the light emitted by the LED is absorbed by one or more phosphors, in which case the emission from the pcLED is entirely from the phosphors. In such cases the phosphor may be selected, for example, to emit light in a narrow spectral region that is not efficiently generated directly by an LED.

Alternatively, pcLEDs may be designed so that only a portion of the light emitted by the LED is absorbed by the phosphors, in which case the emission from the pcLED is a mixture of light emitted by the LED and light emitted by the phosphors. By suitable choice of LED, phosphors, and phosphor composition, such a pcLED may be designed to emit, for example, white light having a desired color temperature and desired color-rendering properties.

Multiple LEDs or pcLEDs can be formed together on a single substrate to form an array. Such arrays can be employed to form active illuminated displays, such as those employed in, e.g., smartphones and smart watches, computer or video displays, augmented-or virtual-reality displays, or signage, or to form adaptive illumination sources, such as those employed in, e.g., automotive headlights, street lighting, camera flash sources, or flashlights (i.e., torches). An array having one or several or many individual devices per millimeter (e.g., nonzero device pitch or spacing of about a millimeter, a few hundred microns, or less than 100 microns, and nonzero separation between adjacent devices less than 100 microns or only a few tens of microns or less) typically is referred to as a miniLED array or a microLED array (alternatively, a μLED array). Such mini-or microLED arrays can in many instances also include phosphor converters as described above; such arrays can be referred to as pc-miniLED or pc-microLED arrays.

### SUMMARY

An inventive light-emitting array includes multiple semiconductor light-emitting diodes (LEDs). Each LED of the array includes first and second doped semiconductor layers and an active layer them, and emits light at a nominal emission vacuum wavelength λ₀ resulting from charge carrier recombination at the active layer. The active layer differs in chemical composition from the first and second semiconductor layers and is between 0.1 nm thick and 1 nm thick. Each LED exhibits a small-signal bandwidth greater than 0.10 GHz. In some instances the doped semiconductor layers can be p-doped and n-doped GaN layers, and the active layer can be a monolayer of a III-nitride compound, e.g., InGaN.

Objects and advantages pertaining to LEDs, pcLEDs, miniLED arrays, pc-miniLED arrays, microLED arrays, and pc-microLED arrays may become apparent upon referring to the examples illustrated in the drawings and disclosed in the following written description or appended claims.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1 shows a schematic cross-sectional view of an example pcLED.

FIGS. 2A and 2B show, respectively, cross-sectional and top schematic views of an example array of pcLEDs.

FIG. 3A shows a schematic cross-sectional view of an example array of pcLEDs arranged with respect to waveguides and a projection lens. FIG. 3B shows an arrangement similar to that of FIG. 3A, but without the waveguides.

FIG. 4A shows a top schematic view of an example miniLED or microLED array and an enlarged section of 3×3 LEDs of the array. FIG. 4B is a side cross-sectional schematic diagram of an example of a close-packed array of multi-colored phosphor-converted LEDS on a monolithic die and substrate.

FIG. 5A is a schematic top view of a portion of an example LED display in which each display pixel is a red, green, or blue phosphor-converted LED pixel. FIG. 5B is a schematic top view of a portion of an example LED display in which each display pixel includes multiple phosphor-converted LED pixels (red, green, and blue) integrated onto a single die that is bonded to a control circuit backplane.

FIG. 6A shows a schematic top view an example electronics board on which an array of pcLEDs may be mounted, and FIG. 6B similarly shows an example array of pcLEDs mounted on the electronic board of FIG. 6A.

FIG. 7A schematically illustrates an example camera flash system. FIG. 7B schematically illustrates an example display system. FIG. 7C shows a block diagram of an example visualization system.

FIG. 8 is a schematic cross-sectional view of a light-emitting array.

FIG. 9 shows plots of simulated modulation bandwidth as a function of current density for three different active layer thicknesses.

FIG. 10 shows plots of simulated internal quantum efficiency as a function of current density for three different active layer thicknesses.

FIG. 11 is a schematic cross-sectional view of a light-emitting array with wavelength-converting elements.

The examples depicted are shown only schematically; all features may not be shown in full detail or in proper proportion; for clarity certain features or structures may be exaggerated or diminished relative to others or omitted entirely; the drawings should not be regarded as being to scale unless explicitly indicated as being to scale. For example, individual LEDs may be exaggerated in their vertical dimensions or layer thicknesses relative to their lateral extent or relative to substrate or phosphor thicknesses. The examples shown should not be construed as limiting the scope of the present disclosure or appended claims.

### DETAILED DESCRIPTION

The following detailed description should be read with reference to the drawings, in which identical reference numbers refer to like elements throughout the different figures. The drawings, which are not necessarily to scale, depict selective examples and are not intended to limit the scope of the inventive subject matter. The detailed description illustrates by way of example, not by way of limitation, the principles of the inventive subject matter. For purposes of simplicity and clarity, detailed descriptions of well-known devices, circuits, and methods may be omitted so as not to obscure the description of the inventive subject matter with unnecessary detail.

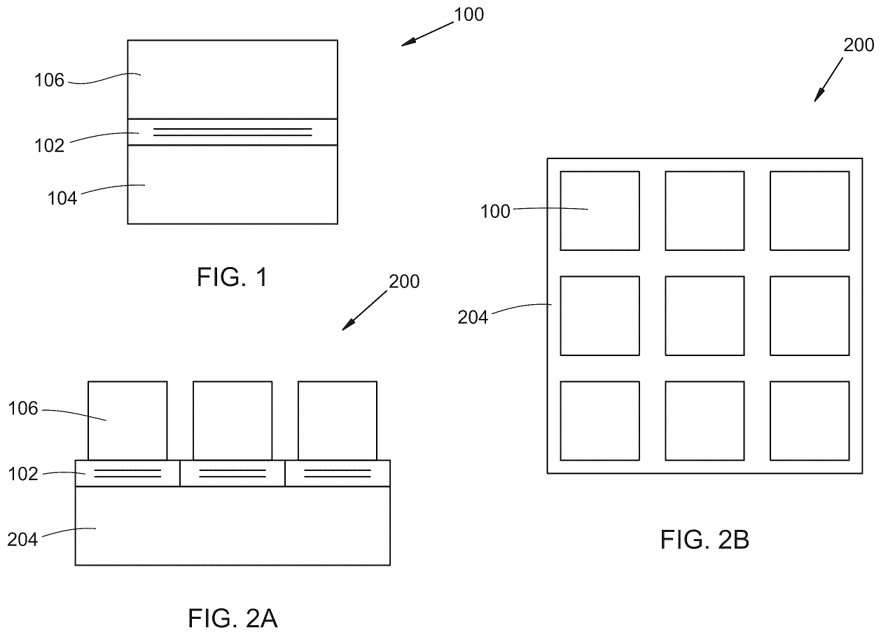

FIG. 1 shows an example of an individual pcLED 100 comprising a semiconductor diode structure 102 disposed on a substrate 104, together considered herein an “LED” or “semiconductor LED”, and a wavelength converting structure (e.g., phosphor layer) 106 disposed on the semiconductor LED. Semiconductor diode structure 102 typically comprises an active region disposed between n-type and p-type layers. Application of a suitable forward bias across the diode structure 102 results in emission of light from the active region. The wavelength of the emitted light is determined by the composition and structure of the active region.

The LED may be, for example, a III-Nitride LED that emits blue, violet, or ultraviolet light. LEDs formed from any other suitable material system and that emit any other suitable wavelength of light may also be used. Other suitable material systems may include, for example, III-Phosphide materials, III-Arsenide materials, other binary, ternary, or quaternary alloys of gallium, aluminum, indium, nitrogen, phosphorus, or arsenic, or II-VI materials.

Any suitable phosphor materials may be used for or incorporated into the wavelength converting structure 106, depending on the desired optical output from the pcLED.

FIGS. 2A-2B show, respectively, cross-sectional and top views of an array 200 of pcLEDs 100, each including a phosphor pixel 106, disposed on a substrate 204. Such an array can include any suitable number of pcLEDs arranged in any suitable manner. In the illustrated example the array is depicted as formed monolithically on a shared substrate, but alternatively an array of pcLEDs can be formed from separate individual pcLEDs (e.g., singulated devices that are assembled onto an array substrate). Individual phosphor pixels 106 are shown in the illustrated example, but alternatively a contiguous layer of phosphor material can be disposed across multiple LEDs 102. In some instances the array 200 can include light barriers (e.g., reflective, scattering, and/or absorbing) between adjacent LEDs 102, phosphor pixels 106, or both. Substrate 204 may optionally include electrical traces or interconnects, or CMOS or other circuitry for driving the LED, and may be formed from any suitable materials.

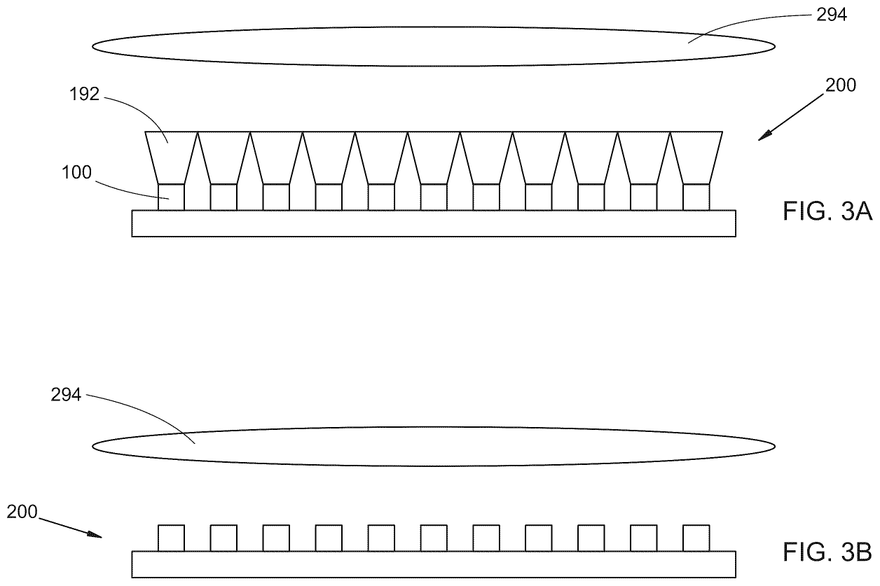

Individual pcLEDs 100 may optionally incorporate or be arranged in combination with a lens or other optical element located adjacent to or disposed on the phosphor layer. Such an optical element, not shown in the figures, may be referred to as a “primary optical element”. In addition, as shown in FIGS. 3A and 3B, a pcLED array 200 (for example, mounted on an electronics board) may be arranged in combination with secondary optical elements such as waveguides, lenses, or both for use in an intended application. In FIG. 3A, light emitted by each pcLED 100 of the array 200 is collected by a corresponding waveguide 192 and directed to a projection lens 294. Projection lens 294 may be a Fresnel lens, for example. This arrangement may be suitable for use, for example, in automobile headlights or other adaptive illumination sources. Other primary or secondary optical elements of any suitable type or arrangement can be included for each pixel, as needed or desired. In FIG. 3B, light emitted by pcLEDs of the array 200 is collected directly by projection lens 294 without use of intervening waveguides. This arrangement may particularly be suitable when pcLEDs can be spaced sufficiently close to each other, and may also be used in automobile headlights as well as in camera flash applications or other illumination sources. A miniLED or microLED display application may use similar optical arrangements to those depicted in FIGS. 3A and 3B, for example. Generally, any suitable arrangement of optical elements (primary, secondary, or both) can be used in combination with the pcLEDs described herein, depending on the desired application.

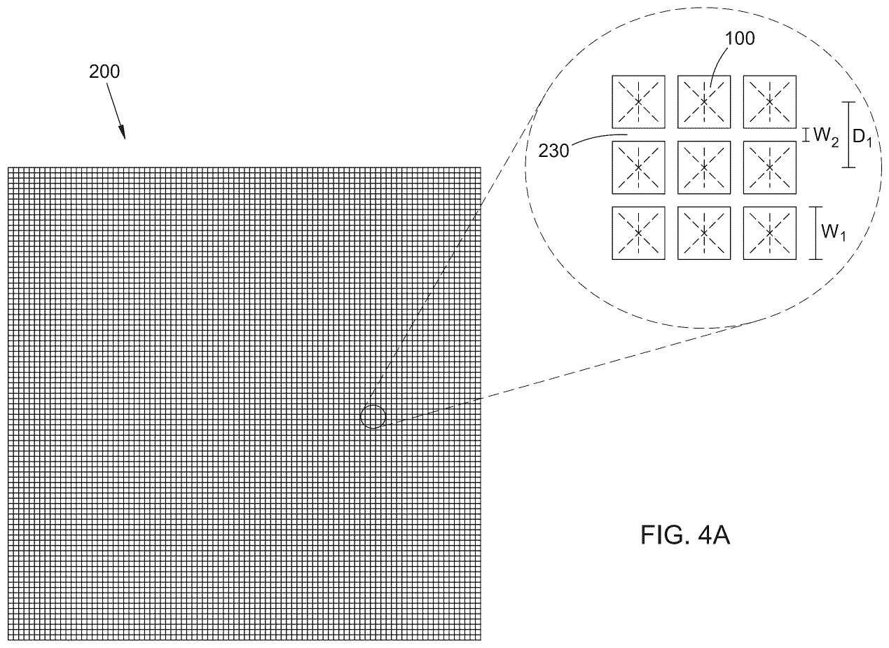

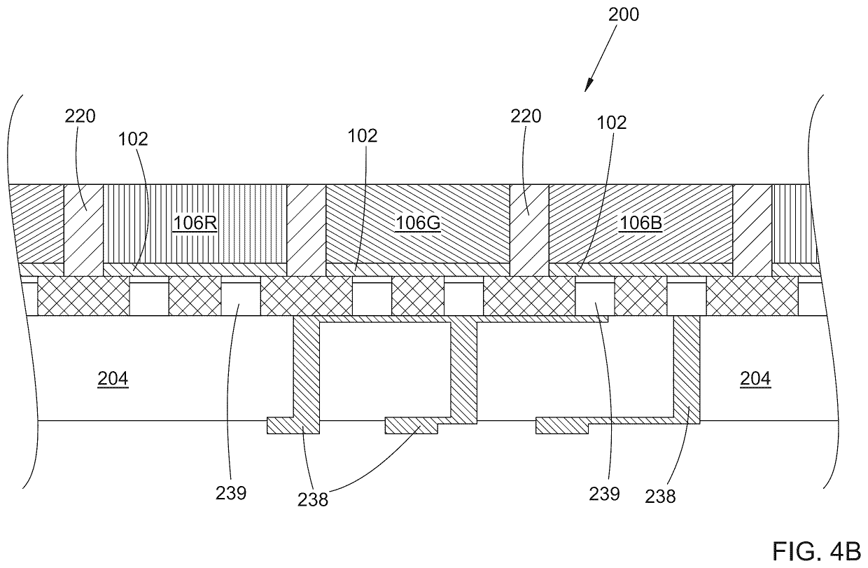

Although FIGS. 2A and 2B show a 3×3 array of nine pcLEDs, such arrays may include for example on the order of 10¹, 10², 10³, 10⁴, or more LEDs, e.g., as illustrated schematically in FIG. 4A. Individual LEDs 100 (i.e., pixels) may have nonzero widths w₁ (e.g., side lengths) in the plane of the array 200, for example, less than or equal to 1 millimeter (mm), less than or equal to 500 microns, less than or equal to 100 microns, or less than or equal to 50 microns. LEDs 100 in the array 200 may be spaced apart from each other by streets, lanes, or trenches 230 having a nonzero width w₂ in the plane of the array 200 of, for example, hundreds of microns, less than or equal to 100 microns, less than or equal to 50 microns, less than or equal to 20 microns, less than or equal to 10 microns, or less than or equal to 5 microns. The pixel pitch or spacing D₁ is the sum of w₁ and w₂. Although the illustrated examples show rectangular pixels arranged in a symmetric matrix, the pixels and the array may have any suitable shape or arrangement, whether symmetric or asymmetric. Multiple separate arrays of LEDs can be combined in any suitable arrangement in any applicable format to form a larger combined array or display.

LEDs having nonzero dimensions w₁ in the plane of the array (e.g., side lengths) of less than or equal to about 0.10 millimeters microns are typically referred to as microLEDs, and an array of such microLEDs may be referred to as a microLED array. LEDs having dimensions w₁ in the plane of the array (e.g., side lengths) of between about 0.10 millimeters and about 1.0 millimeters are typically referred to as miniLEDs, and an array of such miniLEDs may be referred to as a miniLED array.

FIG. 4B is a schematic cross-sectional view of a close packed array 200 of multi-colored, phosphor converted LEDs 100 on a monolithic die and substrate 204. The side view shows GaN LEDs 102 attached to the substrate 204 through metal interconnects 239 (e.g., gold-gold interconnects or solder attached to copper micropillars) and metal interconnects 238. Phosphor pixels 106 are positioned on or over corresponding GaN LED pixels 102. The semiconductor LED pixels 102 or phosphor pixels 106 (often both) can be coated on their sides with a reflective mirror or diffusive scattering layer to form an optical isolation barrier 220. In this example each phosphor pixel 106 is one of three different colors, e.g., red phosphor pixels 106R, green phosphor pixels 106G, and blue phosphor pixels 106B (still referred to generally or collectively as phosphor pixels 106). Such an arrangement can enable use of the LED array 200 as a color display.

The individual LEDs (pixels) in an LED array may be individually addressable, may be addressable as part of a group or subset of the pixels in the array, or may not be addressable. Thus, light emitting pixel arrays are useful for any application requiring or benefiting from fine-grained intensity, spatial, and temporal control of light distribution. These applications may include, but are not limited to, precise special patterning of emitted light from pixel blocks or individual pixels, in some instances including the formation of images as a display device. Depending on the application, emitted light may be spectrally distinct, adaptive over time, and/or environmentally responsive. The light emitting pixel arrays may provide preprogrammed light distribution in various intensity, spatial, or temporal patterns. The emitted light may be based at least in part on received sensor data and may be used for optical wireless communications. Associated electronics and optics may be distinct at a pixel, pixel block, or device level.

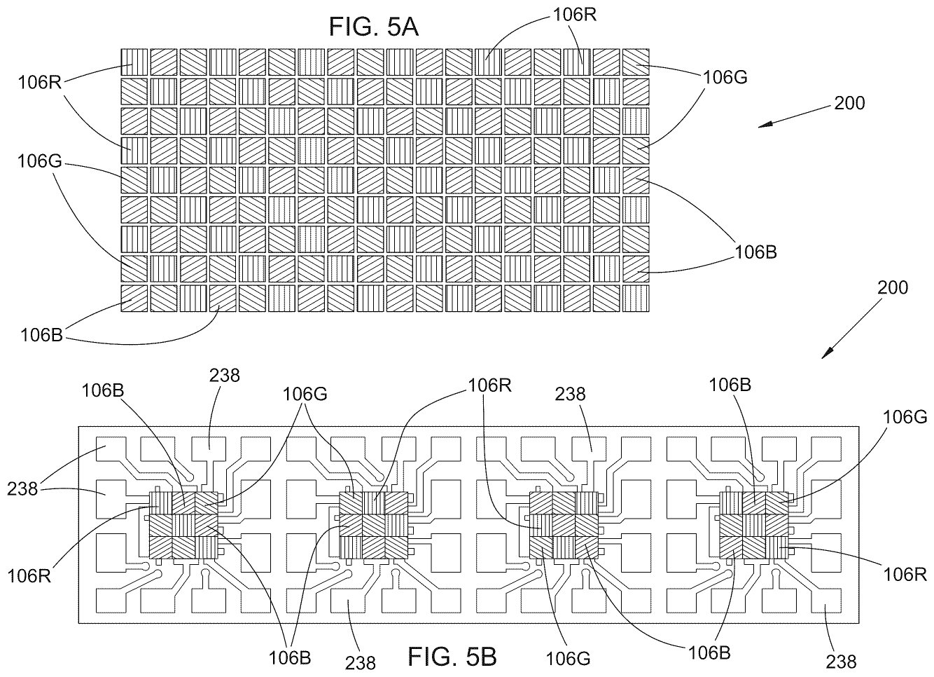

FIGS. 5A and 5B are examples of LED arrays 200 employed in display applications, wherein an LED display includes a multitude of display pixels. In some examples (e.g., as in FIG. 5A), each display pixel comprises a single semiconductor LED pixel 102 and a corresponding phosphor pixel 106R, 106G, or 106B of a single color (red, green, or blue). Each display pixel only provides one of the three colors. In some examples (e.g., as in FIG. 5B), each display pixel includes multiple semiconductor LED pixels 102 and multiple corresponding phosphor pixels 106 of multiple colors. In the example shown each display pixel includes a 3×3 array of semiconductor pixels 102; three of those LED pixels have red phosphor pixels 106R, three have green phosphor pixels 106G, and three have blue phosphor pixels 106B. Each display pixel can therefore produce any desired color combination. In the example shown the spatial arrangement of the different colored phosphor pixels 106 differs among the display pixels; in some examples (not shown) each display pixel can have the same arrangement of the different colored phosphor pixels 106.

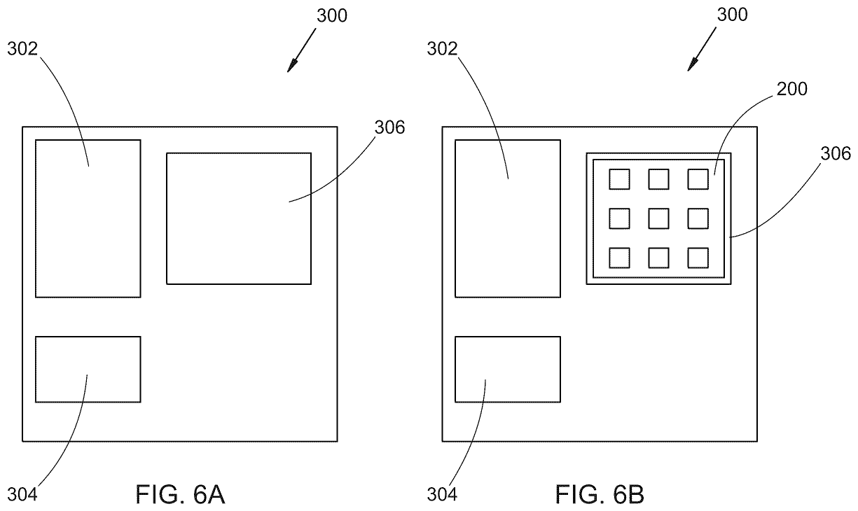

As shown in FIGS. 6A and 6B, a pcLED array 200 may be mounted on an electronics board 300 comprising a power and control module 302, a sensor module 304, and an LED attach region 306. Power and control module 302 may receive power and control signals from external sources and signals from sensor module 304, based on which power and control module 302 controls operation of the LEDs. Sensor module 304 may receive signals from any suitable sensors, for example from temperature or light sensors. Alternatively, pcLED array 200 may be mounted on a separate board (not shown) from the power and control module and the sensor module.

An array of independently operable LEDs or pcLEDs may be used in combination with a lens, lens system, or other optic or optical system (e.g., as described above) to provide illumination that is adaptable for a particular purpose. For example, in operation such an adaptive lighting system may provide illumination that varies by color and/or intensity across an illuminated scene or object and/or is aimed in a desired direction. Beam focus or steering of light emitted by the LED or pcLED array can be performed electronically by activating LEDs or pcLEDs in groups of varying size or in sequence, to permit dynamic adjustment of the beam shape and/or direction without moving optics or changing the focus of the lens in the lighting apparatus. A controller can be configured to receive data indicating locations and color characteristics of objects or persons in a scene and based on that information control LEDs or pcLEDs in an array to provide illumination adapted to the scene. Such data can be provided for example by an image sensor, or optical (e.g., laser scanning) or non-optical (e.g., millimeter radar) sensors. Such adaptive illumination is increasingly important for automotive (e.g., adaptive headlights), mobile device camera (e.g., adaptive flash), AR, VR, and MR applications such as those described below.

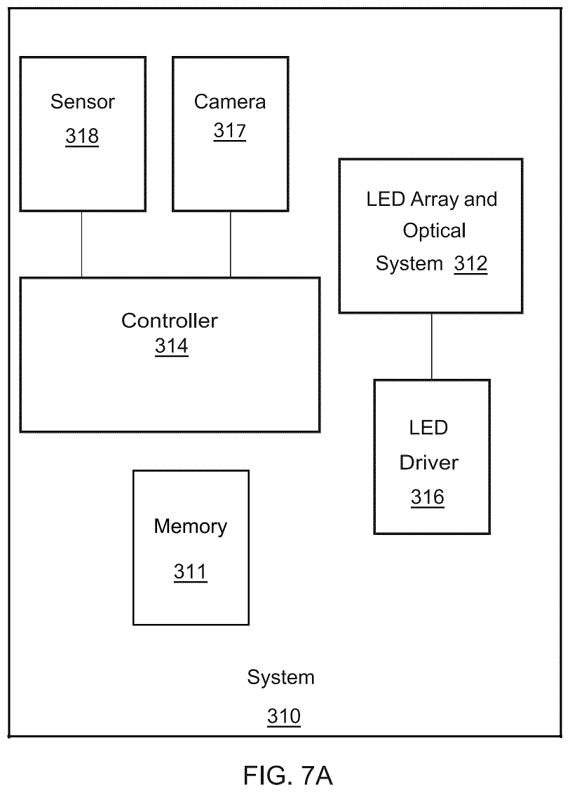

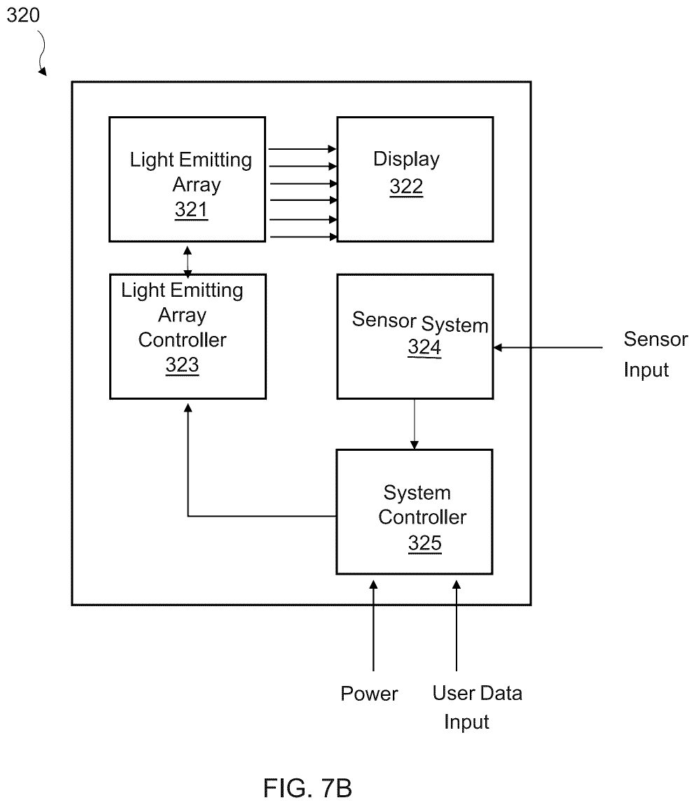

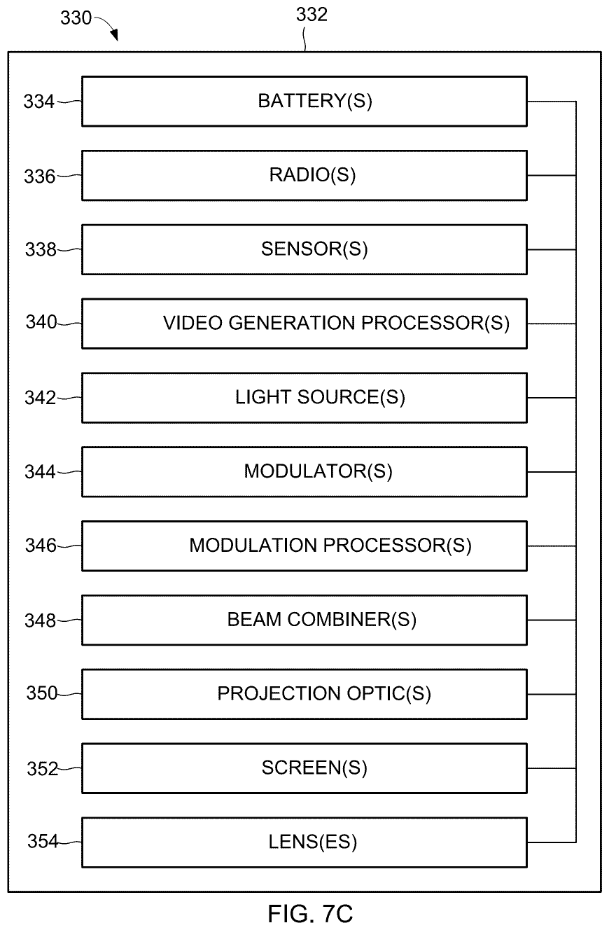

FIG. 7A schematically illustrates an example camera flash system 310 comprising an LED or pcLED array and an optical (e.g., lens) system 312, which may be or comprise an adaptive lighting system as described above in which LEDs or pcLEDs in the array may be individually operable or operable as groups. In operation of the camera flash system, illumination from some or all of the LEDs or pcLEDs in array and optical system 312 may be adjusted-deactivated, operated at full intensity, or operated at an intermediate intensity. The array may be a monolithic array, or comprise one or more monolithic arrays, as described above. The array may be a microLED array, as described above.

Flash system 310 also comprises an LED driver 316 that is controlled by a controller 314, such as a microprocessor. Controller 314 may also be coupled to a camera 317 and to sensors 318 and operate in accordance with instructions and profiles stored in memory 311. Camera 317 and LED or pcLED array and lens system 312 may be controlled by controller 314 to, for example, match the illumination provided by system 312 (i.e., the field of view of the illumination system) to the field of view of camera 317, or to otherwise adapt the illumination provided by system 312 to the scene viewed by the camera as described above. Sensors 318 may include, for example, positional sensors (e.g., a gyroscope and/or accelerometer) and/or other sensors that may be used to determine the position and orientation of system 310.

FIG. 7B schematically illustrates an example display system 320 that includes an array 321 of LEDs or pcLEDs that are individually operable or operable in groups, a display 322, a light emitting array controller 323, a sensor system 324, and a system controller 325. Array 321 may be a monolithic array, or comprise one or more monolithic arrays, as described above. The array may be monochromatic. Alternatively, the array may be a multicolor array in which different LEDs or pcLEDs in the array are configured to emit different colors of light, as described above. The array may therefore be or comprise a monolithic multicolor matrix of individually operable LED or pcLED light emitters, which may for example be microLEDs as described above. A single individually operable LED or pcLED or a group of adjacent such LEDs or pcLEDs in the array may correspond to a single pixel (picture element) in the display. For example, a group of three individually operable adjacent LEDs or pcLEDs comprising a red emitter, a blue emitter, and a green emitter may correspond to a single color-tunable pixel in the display. Similarly, to provide redundancy in the event of a defective LED or pcLED, a group of six individually operable adjacent LEDs or pcLEDs comprising two red emitters, two blue emitters, and two green emitters may correspond to a single color-tunable pixel in the display Array 321 can be used to project light in graphical or object patterns that can for example support AR/VR/MR systems. In some cases the individual emitters can be referred to as pixels even if several are operated together to act as a single pixel of a display.

Sensor input is provided to the sensor system 324, while power and user data input is provided to the system controller 325. In some embodiments modules included in system 320 can be compactly arranged in a single structure, or one or more elements can be separately mounted and connected via wireless or wired communication. For example, array 321, display 322, and sensor system 324 can be mounted on a headset or glasses, with the light emitting array controller and/or system controller 325 separately mounted.

System 320 can incorporate a wide range of optics (not shown) to couple light emitted by array 321 into display 322. Any suitable optics may be used for this purpose.

Sensor system 324 can include, for example, external sensors such as cameras, depth sensors, or audio sensors that monitor the environment, and internal sensors such as accelerometers or two or three axis gyroscopes that monitor an AR/VR/MR headset position. Other sensors can include but are not limited to air pressure, stress sensors, temperature sensors, or any other suitable sensors needed for local or remote environmental monitoring. In some embodiments, control input through the sensor system can include detected touch or taps, gestural input, or control based on headset or display position.

In response to data from sensor system 324, system controller 325 can send images or instructions to the light emitting array controller 323. Changes or modification to the images or instructions can also be made by user data input, or automated data input as needed. User data input can include but is not limited to that provided by audio instructions, haptic feedback, eye or pupil positioning, or connected keyboard, mouse, or game controller.

As noted above, AR, VR, and MR systems may be more generally referred to as examples of visualization systems. In a virtual reality system, a display can present to a user a view of scene, such as a three-dimensional scene. The user can move within the scene, such as by repositioning the user's head or by walking. The virtual reality system can detect the user's movement and alter the view of the scene to account for the movement. For example, as a user rotates the user's head, the system can present views of the scene that vary in view directions to match the user's gaze. In this manner, the virtual reality system can simulate a user's presence in the three-dimensional scene. Further, a virtual reality system can receive tactile sensory input, such as from wearable position sensors, and can optionally provide tactile feedback to the user.

In an augmented reality system, the display can incorporate elements from the user's surroundings into the view of the scene. For example, the augmented reality system can add textual captions and/or visual elements to a view of the user's surroundings. For example, a retailer can use an augmented reality system to show a user what a piece of furniture would look like in a room of the user's home, by incorporating a visualization of the piece of furniture over a captured image of the user's surroundings. As the user moves around the user's room, the visualization accounts for the user's motion and alters the visualization of the furniture in a manner consistent with the motion. For example, the augmented reality system can position a virtual chair in a room. The user can stand in the room on a front side of the virtual chair location to view the front side of the chair. The user can move in the room to an area behind the virtual chair location to view a back side of the chair. In this manner, the augmented reality system can add elements to a dynamic view of the user's surroundings.

FIG. 7C shows a generalized block diagram of an example visualization system 330. The visualization system 330 can include a wearable housing 332, such as a headset or goggles. The housing 332 can mechanically support and house the elements detailed below. In some examples, one or more of the elements detailed below can be included in one or more additional housings that can be separate from the wearable housing 332 and couplable to the wearable housing 332 wirelessly and/or via a wired connection. For example, a separate housing can reduce the weight of wearable goggles, such as by including batteries, radios, and other elements. The housing 332 can include one or more batteries 334, which can electrically power any or all of the elements detailed below. The housing 332 can include circuitry that can electrically couple to an external power supply, such as a wall outlet, to recharge the batteries 334. The housing 332 can include one or more radios 336 to communicate wirelessly with a server or network via a suitable protocol, such as WiFi.

The visualization system 330 can include one or more sensors 338, such as optical sensors, audio sensors, tactile sensors, thermal sensors, gyroscopic sensors, time-of-flight sensors, triangulation-based sensors, and others. In some examples, one or more of the sensors can sense a location, a position, and/or an orientation of a user. In some examples, one or more of the sensors 338 can produce a sensor signal in response to the sensed location, position, and/or orientation. The sensor signal can include sensor data that corresponds to a sensed location, position, and/or orientation. For example, the sensor data can include a depth map of the surroundings. In some examples, such as for an augmented reality system, one or more of the sensors 338 can capture a real-time video image of the surroundings proximate a user.

The visualization system 330 can include one or more video generation processors 340. The one or more video generation processors 340 can receive, from a server and/or a storage medium, scene data that represents a three-dimensional scene, such as a set of position coordinates for objects in the scene or a depth map of the scene. The one or more video generation processors 340 can receive one or more sensor signals from the one or more sensors 338. In response to the scene data, which represents the surroundings, and at least one sensor signal, which represents the location and/or orientation of the user with respect to the surroundings, the one or more video generation processors 340 can generate at least one video signal that corresponds to a view of the scene. In some examples, the one or more video generation processors 340 can generate two video signals, one for each eye of the user, that represent a view of the scene from a point of view of the left eye and the right eye of the user, respectively. In some examples, the one or more video generation processors 340 can generate more than two video signals and combine the video signals to provide one video signal for both eyes, two video signals for the two eyes, or other combinations.

The visualization system 330 can include one or more light sources 342 that can provide light for a display of the visualization system 330. Suitable light sources 342 can include any of the LEDs, pcLEDs, LED arrays, and pcLED arrays discussed above, for example those discussed above with respect to display system 320.

The visualization system 330 can include one or more modulators 344. The modulators 344 can be implemented in one of at least two configurations.

In a first configuration, the modulators 344 can include circuitry that can modulate the light sources 342 directly. For example, the light sources 342 can include an array of light-emitting diodes, and the modulators 344 can directly modulate the electrical power, electrical voltage, and/or electrical current directed to each light-emitting diode in the array to form modulated light. The modulation can be performed in an analog manner and/or a digital manner. In some examples, the light sources 342 can include an array of red light-emitting diodes, an array of green light-emitting diodes, and an array of blue light-emitting diodes, and the modulators 344 can directly modulate the red light-emitting diodes, the green light-emitting diodes, and the blue light-emitting diodes to form the modulated light to produce a specified image.

In a second configuration, the modulators 344 can include a modulation panel, such as a liquid crystal panel. The light sources 342 can produce uniform illumination, or nearly uniform illumination, to illuminate the modulation panel. The modulation panel can include pixels. Each pixel can selectively attenuate a respective portion of the modulation panel area in response to an electrical modulation signal to form the modulated light. In some examples, the modulators 344 can include multiple modulation panels that can modulate different colors of light. For example, the modulators 344 can include a red modulation panel that can attenuate red light from a red light source such as a red light-emitting diode, a green modulation panel that can attenuate green light from a green light source such as a green light-emitting diode, and a blue modulation panel that can attenuate blue light from a blue light source such as a blue light-emitting diode.

In some examples of the second configuration, the modulators 344 can receive uniform white light or nearly uniform white light from a white light source, such as a white-light light-emitting diode. The modulation panel can include wavelength-selective filters on each pixel of the modulation panel. The panel pixels can be arranged in groups (such as groups of three or four), where each group can form a pixel of a color image. For example, each group can include a panel pixel with a red color filter, a panel pixel with a green color filter, and a panel pixel with a blue color filter. Other suitable configurations can also be used.

The visualization system 330 can include one or more modulation processors 346, which can receive a video signal, such as from the one or more video generation processors 340, and, in response, can produce an electrical modulation signal. For configurations in which the modulators 344 directly modulate the light sources 342, the electrical modulation signal can drive the light sources 344. For configurations in which the modulators 344 include a modulation panel, the electrical modulation signal can drive the modulation panel.

The visualization system 330 can include one or more beam combiners 348 (also known as beam splitters 348), which can combine light beams of different colors to form a single multi-color beam. For configurations in which the light sources 342 can include multiple light-emitting diodes of different colors, the visualization system 330 can include one or more wavelength-sensitive (e.g., dichroic) beam splitters 348 that can combine the light of different colors to form a single multi-color beam.

The visualization system 330 can direct the modulated light toward the eyes of the viewer in one of at least two configurations. In a first configuration, the visualization system 330 can function as a projector, and can include suitable projection optics 350 that can project the modulated light onto one or more screens 352. The screens 352 can be located a suitable distance from an eye of the user. The visualization system 330 can optionally include one or more lenses 354 that can locate a virtual image of a screen 352 at a suitable distance from the eye, such as a close-focus distance, such as 500 mm, 750 mm, or another suitable distance. In some examples, the visualization system 330 can include a single screen 352, such that the modulated light can be directed toward both eyes of the user. In some examples, the visualization system 330 can include two screens 352, such that the modulated light from each screen 352 can be directed toward a respective eye of the user. In some examples, the visualization system 330 can include more than two screens 352. In a second configuration, the visualization system 330 can direct the modulated light directly into one or both eyes of a viewer. For example, the projection optics 350 can form an image on a retina of an eye of the user, or an image on each retina of the two eyes of the user.

For some configurations of augmented reality systems, the visualization system 330 can include an at least partially transparent display, such that a user can view the user's surroundings through the display. For such configurations, the augmented reality system can produce modulated light that corresponds to the augmentation of the surroundings, rather than the surroundings itself. For example, in the example of a retailer showing a chair, the augmented reality system can direct modulated light, corresponding to the chair but not the rest of the room, toward a screen or toward an eye of a user.

For purposes of the present disclosure and appended claims, any arrangement of a layer, surface, substrate, diode structure, or other structure “on,” “over,” or “against” another such structure shall encompass arrangements with direct contact between the two structures as well as arrangements including some intervening structure between them. Conversely, any arrangement of a layer, surface, substrate, diode structure, or other structure “directly on,” “directly over,” or “directly against” another such structure shall encompass only arrangements with direct contact between the two structures. For purposes of the present disclosure and appended claims, a layer, structure, or material described as “transparent” and “substantially transparent” shall exhibit, at the nominal emission vacuum wavelength λ₀, a level of optical transmission that is sufficiently high, or a level of optical loss (due to absorption, scattering, or other loss mechanism) that is sufficiently low, that the light-emitting device can function within operationally acceptable parameters (e.g., output power or luminance, conversion or extraction efficiency, or other figures-of-merit including any described herein).

An LED can be employed as a modulated light source for transmitting data. An electrical signal, modulated to encode the transmitted data (according to any suitable modulation protocol) can be used to drive the LED, so that light emitted by the LED is also modulated to encode that transmitted data. The modulated output light from the LED can be directed to propagate through an optical fiber or can be allowed to propagate through space (perhaps redirected or refocused by one or more optical elements). A photodetector that receives the modulated LED light produces an electrical signal that is modulated to encode the transmitted data, from which the transmitted data can be extracted using a suitable demodulation process.

The bandwidth of the LED limits the rate at which data can be transmitted in this way. Typically bandwidth of at least 100 MHz or a few hundred MHz up to 1 GHz or more are considered desirable for data transmission. Not all LEDs exhibit such large bandwidth. In particular, an LED exhibiting such bandwidths is typically relatively small. Accordingly, an array of microLEDs can be usefully employed as a modulated light source for data transmission. In many cases the data transmission can be done by the LED array in parallel with another function, e.g., being used as a display or as an illumination source. The typical modulation speeds employed for data transmission are imperceptible to the human eye, enabling such parallel use of the LED array.

Previously, to achieve a suitably large modulation bandwidth for data transmission, an LED would need to be driven at relatively large current density, e.g., on the order of 10 kA/cm² or more, to achieve sufficient high carrier density and recombination rate in the LED active layer. It would be desirable to provide an LED or LED array exhibiting sufficiently large achieve large modulation without requiring such high current density.

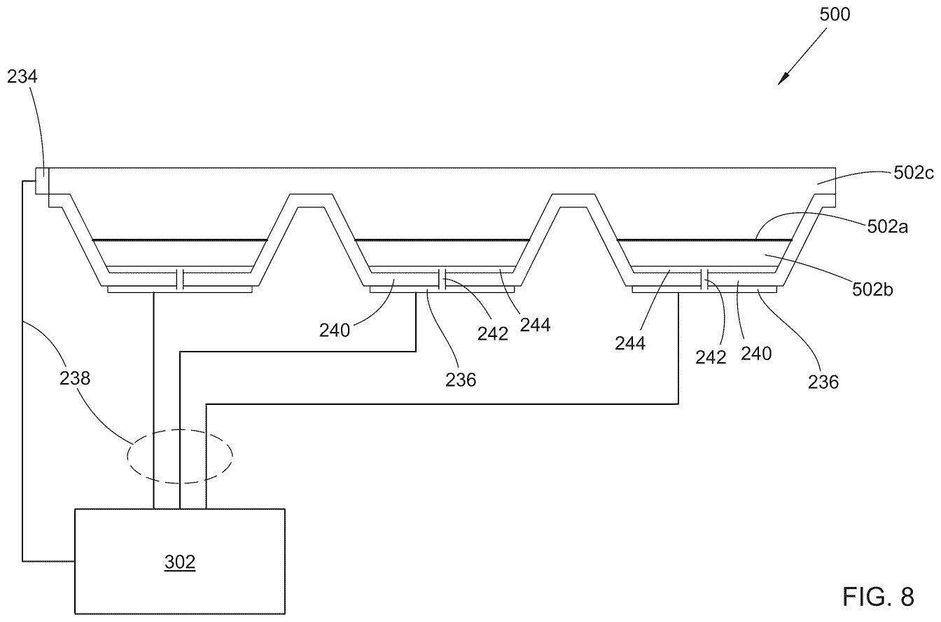

Accordingly, an inventive light-emitting array 500 includes multiple semiconductor light-emitting diodes (LEDs) arranged in the array 500, one or more first electrical contacts 236, and one or more second electrical contacts 234. An example is shown in FIG. 8, which shows a group of three LEDs that can represent the entire array 500 or only a portion of a larger array 500. In some examples (include that shown in FIG. 8) the first electrical contacts 236 are electrically connected to the LEDs by an electrically conductive via 242 (through a dielectric layer 240) and a transparent electrode layer 244; in such examples the dielectric layer 240 and the contact layer 236 can form a composite reflector. In some other examples (not shown) the contact layer 236 can be in direct electrical contact with the LED, without the dielectric layer 240, via 242, or electrode layer 244. The electrical contacts 234/236 generally can be of any suitable type or arrangement.

Each LED of the array 500 includes first and second doped semiconductor layers 502b and 502c and an active layer 502a between them. The LED is arranged for emitting light at a nominal emission vacuum wavelength λ₀ resulting from charge carrier recombination at the active layer 502a. The active layer 502a differs in chemical composition from the first and second semiconductor layers 502b/502c and is between 0.1 nm thick and 1 nm thick. Each LED exhibits a small-signal bandwidth greater than 0.10 GHz, in some examples at a nonzero current density less than 2000 A/cm². In some examples each LED can exhibit a small-signal bandwidth greater than 0.5 GHz at a current density between 1000 A/cm² and 2000 A/cm²; in some examples each LED can exhibit a small-signal bandwidth greater than 1.0 GHz at a current density of 2000 A/cm². In some examples the active layer of each LED can be less than 0.5 nm thick; in some examples the active layer of each LED can be less than 0.3 nm thick.

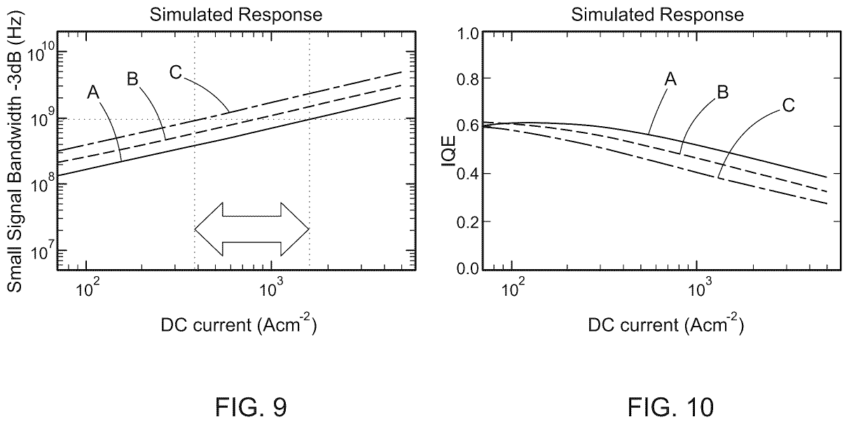

It is proposed (but not required) that the thin active layer 502a causes crowding of recombining charge carriers into a thinner active layer 502a. The resulting increased carrier density results in a correspondingly faster recombination rate and increased bandwidth. Other proposed (but not required) mechanisms can include one or both of: suppression of the quantum-confined Stark effect by enhancing electron-hole overlap in the active layer 502a, or increase of non-radiative Auger processes which can facilitate increased modulation bandwidth. Simulations of modulation bandwidth as a function of current density for three different active layer thicknesses are shown in FIG. 9, for active layers 502a that are 1 nm thick (curve A), 0.5 nm thick (curve B), and 0.25 nm thick (curve C), and illustrate the increase in modulation bandwidth with decreasing active layer thickness.

In some examples (e.g., as in FIG. 8) the LEDs can be formed monolithically from a common substrate. In the example of FIG. 8, the doped semiconductor layer 502c spans multiple LEDs of the array 500, while trenches divide the doped semiconductor layer 502b and the active layer 502a into discrete areal regions to form corresponding discrete LEDs of the array. In some examples the trenches can extend partly through the semiconductor layer 502c; in some other examples (not shown) the trenches can extend entirely through the semiconductor layer 502c, in which case an additional substrate would be needed to hold the LEDs together arranged in the array 500. In some examples each LED can have a nonzero width less than 200 μm, less than 100 μm, less than 50 μm, or even smaller. “Width” as used herein designates the diameter of a circular LED, the long axis of an elliptical LED, the longer side of a rectangular LED, or a maximum transverse length across an LED of some other shape. “Nonzero” refers to a width that, however small it might be, still permits the structure having that nonzero width to function as an LED.

In some examples the diode structure (i.e., one or more of layers 502a/502b/502c) can include one or more doped or undoped III-V, II-VI, or Group IV semiconductor materials or alloys or mixtures thereof. In some examples the nominal emission vacuum wavelength λ₀ can be greater than 0.20 μm, greater than 0.4 μm, greater than 0.8 μm, less than 10. μm, less than 2.5 μm, or less than 1.0 μm. In some examples the first and second semiconductor layers 502b and 502B and the active layer 502c of each LED include one or more III-V semiconductor materials. In some examples, the first semiconductor layer 502b can comprise p-doped GaN, the second semiconductor layer 502c can comprise n-doped GaN, and the active layer 502a can comprise a III-nitride compound, e.g., InGaN. More generally, the material of the active layer 502a exhibits a smaller bandgap than that of the semiconductor layers 502b/502c. In some examples the active layer 502a of each LED can comprise a monolayer of the III-nitride compound. In some examples the areal density of indium can vary with position along the active layer 502a of each LED. It is proposed (but not required) that such variations can lead to localized regions of increased carrier density, further enhancing the recombination rate and modulation bandwidth.

Despite the thin active layer 502a, in some examples each LED can still exhibit an internal quantum efficiency (IQE) greater than 0.3 at a current density between 100 A/cm² and 2000 A/cm². In some examples each LED can exhibit an internal quantum efficiency greater than 0.4 at a current density between 100 A/cm² and 2000 A/cm². Simulated examples of internal quantum efficiency (IQE) as a function of current density for three different active layer thicknesses are illustrated in FIG. 10, for active layers 502a that are 1 nm thick (curve A), 0.5 nm thick (curve B), and 0.25 nm thick (curve C), and show a decrease in IQE with decreasing active layer thickness. In some examples high-bandwidth LEDs can be operated even with IQE as low as 0.1.

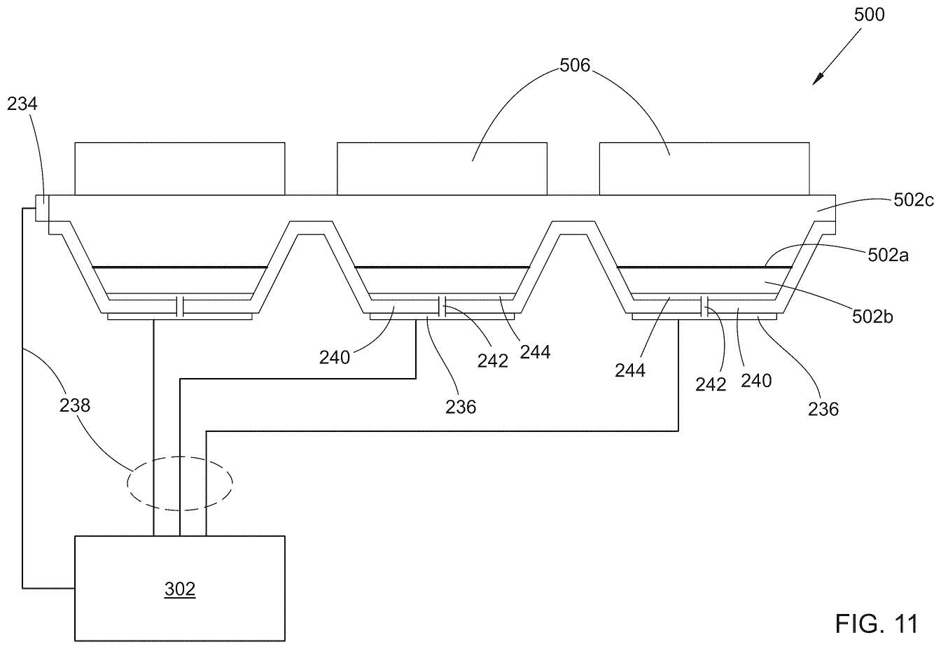

In some examples one or some or all of the LEDs of the array 500 are arranged as so-called direct emitters, i.e., light emitted at the nominal wavelength λ₀ by the active layer 502a of a given LED is the output of that LED. In some other examples (e.g., as in FIG. 11) one or some or all of the LEDs of the array 500 can include a corresponding wavelength-converting element 506. Each wavelength-converting element 506 absorbs light at the vacuum wavelength λ₀ and emits light at a nominal vacuum wavelength λ₁ that is longer than λ₀. The light at wavelength λ₁ forms at least a portion of, and in some instance the entirety of, the output of the corresponding LED. In some examples all of the wavelength-converting elements 506 of the array 500 can emit light at the same converted wavelength λ₁; in some examples different wavelength-converting elements 506 of the array 500 can emit light at differing wavelengths λ₁ (e.g., an RGB arrangement as described above).

Many wavelength-converting material are phosphors having relatively long emission lifetime (e.g., 100s of nanoseconds, or microseconds). Such long lifetimes would limit the modulation bandwidth of a wavelength-converted LED, with the long emission lifetime effectively “washing out” large modulation frequencies. In some examples in which the light emitted at the wavelength λ₀ forms at least a portion of the output of the LED, a long emission lifetime might be tolerable; the high-speed modulation would still appear on the portion of the output light at λ₀. In some examples, particularly those in which the entire output is at the wavelength λ₁, a wavelength-converting element 506 exhibiting an emission lifetime less than 20 ns, or less than 10 ns, can be employed; the high-speed modulation would appear on the wavelength-converted output light at λ₁. In some examples fluorescent quantum dots or fluorescent dyes can be employed for wavelength conversion with a sufficiently short emission lifetime.

In some examples the light-emitting array 500 can include a set of multiple independent electrically conductive traces or interconnects 238 connected to the first electrical contacts 236. Each LED can be in electrical contact with only one of the first electrical contacts 236, and each first electrical contact 236 can be connected to a single corresponding one of the traces or interconnects 238. Each contact 236 can be connected to a trace 238 that is different from a corresponding trace 238 connected to at least one other contact 236. A drive circuit 302 can be connected to the first and second electrical contacts 236 and 234 by the electrical traces or interconnects 238. The drive circuit 302 can provide electrical drive current that flows through the array 500 and causes the array to emit light. The drive circuit 500 can be structured and connected so that (i) corresponding portions of the electrical drive current flow through one or more of the corresponding first electrical contacts 236 as corresponding pixel currents, and (ii) at least one of the pixel currents is modulated so as to encode transmitted data. That modulated pixel current results in light emitted by the corresponding LED(s) being modulated to encode the transmitted data.

For simultaneously operating the array 500 as a display while transmitting data, the drive circuit 302 can be further structured and connected so that each pixel current magnitude differs from the corresponding pixel current magnitude of at least one other of the LEDs of the array, so that the array 500 can function as a static or dynamic display. For a dynamic display, the drive circuit 302 can be operated to provide a first specified spatial distribution of pixel current magnitudes to the LEDs of the array 500, to cause the array 500 to emit light according to a corresponding first spatial distribution of light emission intensity across the array (e.g., text and/or images). Then the drive circuit 302 can be operated to provide a second, different specified spatial distribution of pixel current magnitudes, causing the array to emit light according to a corresponding second spatial distribution of light emission intensity (e.g., new text or an altered or different image). While those differing spatial distributions are being emitted, the drive circuit 302 can also be operated to provide a modulated pixel current to one or more of the LEDs. That modulated pixel current can be modulated to encode transmitted data, so that light emitted by the array includes at least a portion that is modulated to encode the transmitted data.

The example inventive arrangements of the LED array 500 disclosed herein can be suitably employed in any device comprising or incorporating an LED array, including any of those disclosed herein.

An inventive light-emitting array can be made by forming a first one of the doped semiconductor layers (typically on a substrate, e.g., a sapphire substrate), forming the active layer 502a on the first-formed semiconductor layer, and then forming the other one of the doped semiconductor layers on the active layer 502a. In some examples the first-formed layer can be an n-doped GaN layer 502c, the active layer 502a can be a III-nitride compound, and the second-formed layer can be a p-doped GaN layer 502b. At least the active layer 502a and the p-doped GaN layer 502b are divided into discrete areal regions to form corresponding discrete light-emitting diodes (LEDs) of the array 500. The trenches dividing the LEDs can optionally extend partly or entirely through the n-doped GaN layer. In some examples the LED array 500 can be separated from the substrate on which the n-GaN layer 502c was formed. In other examples, including those in which trenches extend entirely through the n-GaN layer 502c, the LED array 500 can be left attached to the substrate.

In addition to the preceding, the following example embodiments fall within the scope of the present disclosure or appended claims. Any given Example below that refers to one or more or all preceding Examples shall be understood to refer to only those preceding Examples with which the given Example is not inconsistent, and to exclude those preceding Examples with which the given Example is inconsistent.

Example 1. A light-emitting array comprising: multiple semiconductor light-emitting diodes (LEDs) arranged in the array, each LED of the array comprising first and second doped semiconductor layers and an active layer therebetween so that the LED is arranged for emitting light at a nominal emission vacuum wavelength λ₀ resulting from charge carrier recombination at the active layer, the active layer differing in chemical composition from the first and second semiconductor layers and being between 0.1 nm thick and 1 nm thick; one or more first electrical contacts that are in electrical contact with the first semiconductor layers of the LEDs; and one or more second electrical contacts that are in electrical contact with the second semiconductor layers of the LEDs, each LED exhibiting a small-signal bandwidth greater than 0.10 GHz.

Example 2. The light-emitting array of Example 1, each LED exhibiting a small-signal bandwidth greater than 0.10 GHz at a nonzero current density less than 2000 A/cm².

Example 3. The light-emitting array of Example 1, each LED exhibiting a small-signal bandwidth greater than 0.5 GHz at a current density between 1000 A/cm² and 2000 A/cm².

Example 4. The light-emitting array of Example 1, each LED exhibiting a small-signal bandwidth greater than 1.0 GHz at a current density of 2000 A/cm².

Example 5. The light-emitting array of any one of Examples 1 through 4, the active layer of each LED being less than 0.5 nm thick.

Example 6. The light-emitting array of any one of Examples 1 through 4, the active layer of each LED being less than 0.3 nm thick.

Example 7. The light-emitting array of any one of Examples 1 through 6, each LED having a nonzero width less than 200 μm.

Example 8. The light-emitting array of any one of Examples 1 through 6, each LED having a nonzero width less than 100 μm.

Example 9. The light-emitting array of any one of Examples 1 through 6, each LED having a nonzero width less than 50 μm.

Example 10. The light-emitting array of any one of Examples 1 through 9, the first and second semiconductor layers or, the active layer of each LED including one or more III-V semiconductor materials.

Example 11. The light-emitting array of Example 10, the first semiconductor layer of each LED comprising p-doped GaN, the second semiconductor layer of each LED comprising n-doped GaN, and the active layer of each LED comprising a III-nitride compound.

Example 12. The light-emitting array of any one of Examples 10 or 11, areal density of indium varying with position along the active layer of each LED.

Example 13. The light-emitting array of any one of Examples 11 or 12, the active layer of each LED comprising a monolayer of the III-nitride compound.

Example 14. The light-emitting array of any one of Examples 1 through 13, each LED exhibiting an internal quantum efficiency greater than 0.1.

Example 15. The light-emitting array of any one of Examples 1 through 13, each LED exhibiting an internal quantum efficiency greater than 0.3 at a current density between 100 A/cm² and 2000 A/cm².

Example 16. The light-emitting array of any one of Examples 1 through 13, each LED exhibiting an internal quantum efficiency greater than 0.4 at a current density between 100 A/cm² and 2000 A/cm².

Example 17. The light-emitting array of any one of Examples 1 through 16, one or more of the LEDs including a corresponding wavelength-converting element that absorbs light at the vacuum wavelength λ₀ and emits light at a nominal vacuum wavelength A1 that is longer than λ₀, each wavelength-converting element exhibiting an emission lifetime less than 20 ns.

Example 18. The light-emitting array of Example 17, each wavelength-converting element exhibiting an emission lifetime less than 10 ns.

Example 19. The light-emitting array of any one of Examples 1 through 18, further comprising: a set of multiple independent electrically conductive traces or interconnects connected to the first electrical contacts, each LED being in electrical contact with only one of the first electrical contacts, each first electrical contact being connected to a single corresponding one of the traces or interconnects that is different from a corresponding trace or interconnect connected to at least one other first electrical contact; and a drive circuit connected to the first and second electrical contacts by the electrical traces or interconnects, the drive circuit being structured and connected so as to provide electrical drive current that flows through the array and causes the array to emit light, and that is further structured and connected so that (i) corresponding portions of the electrical drive current flow through one or more of the corresponding first electrical contacts as corresponding pixel currents, and (ii) at least one of the pixel currents is modulated so as to encode transmitted data, resulting in light emitted by the corresponding LEDs being modulated to encode the transmitted data.

Example 20. A method for using the light-emitting array of Example 19, the method comprising: (A) operating the drive circuit to provide one or more pixel currents to one or more of the corresponding first electrical contacts, causing the array to emit light; and (B) while operating the drive circuit according to part (A), operating the drive circuit to provide a modulated pixel current to one or more of the LEDs, the modulated pixel current being modulated to encode transmitted data, so that light emitted by the array includes at least a portion that is modulated to encode the transmitted data.

Example 21. The light-emitting array of Example 19, the drive circuit being further structured and connected so that each pixel current magnitude differs from the corresponding pixel current magnitude of at least one other of the LEDs of the array, the array being arranged as a display.

Example 22. A method for using the light-emitting array of Example 21, the method comprising: (A) operating the drive circuit to provide a first specified spatial distribution of pixel current magnitudes to the LEDs of the array, causing the array to emit light according to a corresponding first spatial distribution of light emission intensity across the array; (B) operating the drive circuit to provide a second, different specified spatial distribution of pixel current magnitudes, causing the array to emit light according to a corresponding second spatial distribution of light emission intensity across the array that differs from the first spatial distribution of light emission intensity; and (C) while operating the drive circuit according to one or both of parts (A) or (B), operating the drive circuit to provide a modulated pixel current to one or more of the LEDs, the modulated pixel current being modulated to encode transmitted data, so that light emitted by the array includes at least a portion that is modulated to encode the transmitted data.

Example 23. A method for making a light-emitting array, including any of the light-emitting arrays of Examples 1 through 19 or Example 21, the method comprising: (A) forming, on a layer of n-doped GaN, an active layer comprising a III-nitride compound, the active layer being between 0.1 nm thick and 1 nm thick; (B) forming, on the active layer, a layer of p-doped GaN, so that the n-doped GaN layer, the p-doped GaN layer, and the active layer therebetween form a light-emitting diode structure; and (C) dividing at least the active layer and the p-doped GaN layer into discrete areal regions to form corresponding discrete light-emitting diodes (LEDs) of the array, each LED being arranged for emitting light at a nominal emission vacuum wavelength λ₀ resulting from charge carrier recombination at the active layer, each LED exhibiting a small-signal bandwidth greater than 0.10 GHz.

Example 24. The method of Example 23 further comprising forming the active layer with an areal density of indium varying with position along the active layer of each LED.

Example 25. The method of any one of Examples 23 or 24 further comprising forming the active layer as a monolayer of the III-nitride compound.

This disclosure is illustrative and not limiting. Further modifications will be apparent to one skilled in the art in light of this disclosure and are intended to fall within the scope of the present disclosure or appended claims. It is intended that equivalents of the disclosed example embodiments and methods, or modifications thereof, shall fall within the scope of the present disclosure or appended claims.

In the foregoing Detailed Description, various features may be grouped together in several example embodiments for the purpose of streamlining the disclosure. This method of disclosure is not to be interpreted as reflecting an intention that any claimed embodiment requires more features than are expressly recited in the corresponding claim. Rather, as the appended claims reflect, inventive subject matter may lie in less than all features of any single disclosed example embodiment. Therefore, the present disclosure shall be construed as implicitly disclosing any embodiment having any suitable subset of one or more features-which features are shown, described, or claimed in the present application-including those subsets that may not be explicitly disclosed herein. A “suitable” subset of features includes only features that are neither incompatible nor mutually exclusive with respect to any other feature of that subset. Accordingly, the appended claims are hereby incorporated in their entirety into the Detailed Description, with each claim standing on its own as a separate disclosed embodiment. In addition, each of the appended dependent claims shall be interpreted, only for purposes of disclosure by said incorporation of the claims into the Detailed Description, as if written in multiple dependent form and dependent upon all preceding claims with which it is not inconsistent. It should be further noted that the cumulative scope of the appended claims can, but does not necessarily, encompass the whole of the subject matter disclosed in the present application.

The following interpretations shall apply for purposes of the present disclosure and appended claims. The words “comprising,” “including,” “having,” and variants thereof, wherever they appear, shall be construed as open ended terminology, with the same meaning as if a phrase such as “at least” were appended after each instance thereof, unless explicitly stated otherwise. The article “a” shall be interpreted as “one or more” unless “only one,” “a single,” or other similar limitation is stated explicitly or is implicit in the particular context; similarly, the article “the” shall be interpreted as “one or more of the” unless “only one of the,” “a single one of the,” or other similar limitation is stated explicitly or is implicit in the particular context. The conjunction “or” is to be construed inclusively unless: (i) it is explicitly stated otherwise, e.g., by use of “either . . . or,” “only one of,” or similar language; or (ii) two or more of the listed alternatives are understood or disclosed (implicitly or explicitly) to be incompatible or mutually exclusive within the particular context. In that latter case, “or” would be understood to encompass only those combinations involving non-mutually-exclusive alternatives. In one example, each of “a dog or a cat,” “one or more of a dog or a cat,” and “one or more dogs or cats” would be interpreted as one or more dogs without any cats, or one or more cats without any dogs, or one or more of each.

For purposes of the present disclosure or appended claims, when a numerical quantity is recited (with or without terms such as “about,” “about equal to,” “substantially equal to,” “greater than about,” “less than about,” and so forth), standard conventions pertaining to measurement precision, rounding error, and significant digits shall apply, unless a differing interpretation is explicitly set forth. For null quantities described by phrases such as “prevented,” “absent,” “eliminated,” “equal to zero,” “negligible,” and so forth (with or without terms such as “substantially” or “about”), each such phrase shall denote the case wherein the quantity in question has been reduced or diminished to such an extent that, for practical purposes in the context of the intended operation or use of the disclosed or claimed apparatus or method, the overall behavior or performance of the apparatus or method does not differ from that which would have occurred had the null quantity in fact been completely removed, exactly equal to zero, or otherwise exactly nulled.

For purposes of the present disclosure and appended claims, any labelling of elements, steps, limitations, or other portions of an embodiment, example, or claim (e.g., first, second, third, etc., (a), (b), (c), etc., or (i), (ii), (iii), etc.) is only for purposes of clarity, and shall not be construed as implying any sort of ordering or precedence of the portions so labelled. If any such ordering or precedence is intended, it will be explicitly recited in the embodiment, example, or claim or, in some instances, it will be implicit or inherent based on the specific content of the embodiment, example, or claim. In the appended claims, if the provisions of 35 USC § 112(f) are desired to be invoked in an apparatus claim, then the word “means” will appear in that apparatus claim. If those provisions are desired to be invoked in a method claim, the words “a step for” will appear in that method claim. Conversely, if the words “means” or “a step for” do not appear in a claim, then the provisions of 35 USC § 112(f) are not intended to be invoked for that claim.

If any one or more disclosures are incorporated herein by reference and such incorporated disclosures conflict in part or whole with, or differ in scope from, the present disclosure, then to the extent of conflict, broader disclosure, or broader definition of terms, the present disclosure controls. If such incorporated disclosures conflict in part or whole with one another, then to the extent of conflict, the later-dated disclosure controls.

The Abstract is provided as required as an aid to those searching for specific subject matter within the patent literature. However, the Abstract is not intended to imply that any elements, features, or limitations recited therein are necessarily encompassed by any particular claim. The scope of subject matter encompassed by each claim shall be determined by the recitation of only that claim.

What is claimed is:

1. A light-emitting array comprising: multiple semiconductor light-emitting diodes (LEDs) arranged in the array, each LED of the array comprising first and second doped semiconductor layers and an active layer therebetween so that the LED is arranged for emitting light at a nominal emission vacuum wavelength λ₀ resulting from charge carrier recombination at the active layer, the active layer differing in chemical composition from the first and second semiconductor layers and being between 0.1 nm thick and 1 nm thick; one or more first electrical contacts that are in electrical contact with the first semiconductor layers of the LEDs; and one or more second electrical contacts that are in electrical contact with the second semiconductor layers of the LEDs, each LED exhibiting a small-signal bandwidth greater than 0.10 GHz.

2. The light-emitting array of claim 1, each LED exhibiting a small-signal bandwidth greater than 0.10 GHz at a nonzero current density less than 2000 A/cm².

3. The light-emitting array of claim 1, each LED exhibiting a small-signal bandwidth greater than 0.5 GHz at a current density between 1000 A/cm² and 2000 A/cm².

4. The light-emitting array of claim 1, each LED exhibiting a small-signal bandwidth greater than 1.0 GHz at a current density of 2000 A/cm².

5. The light-emitting array of claim 1, the active layer of each LED being less than 0.5 nm thick.

6. The light-emitting array of claim 1, each LED having a nonzero width less than 200 μm.

7. The light-emitting array of claim 1, the first semiconductor layer of each LED comprising p-doped GaN, the second semiconductor layer of each LED comprising n-doped GaN, and the active layer of each LED comprising one or more III-nitride compounds.

8. The light-emitting array of claim 7, areal density of indium varying with position along the active layer of each LED.

9. The light-emitting array of claim 7, the active layer of each LED comprising a monolayer of a III-nitride compound.

10. The light-emitting array of claim 1, each LED exhibiting an internal quantum efficiency greater than 0.1.

11. The light-emitting array of claim 1, each LED exhibiting an internal quantum efficiency greater than 0.3 at a current density between 100 A/cm² and 2000 A/cm².

12. The light-emitting array of claim 1, one or more of the LEDs including a corresponding wavelength-converting element that absorbs light at the vacuum wavelength λ₀ and emits light at a nominal vacuum wavelength λ₁ that is longer than λ₀, each wavelength-converting element exhibiting an emission lifetime less than 20 ns.

13. The light-emitting array of claim 12, each wavelength-converting element exhibiting an emission lifetime less than 10 ns.

14. The light-emitting array of claim 1 further comprising:
a set of multiple independent electrically conductive traces or interconnects connected to the first electrical contacts, each LED being in electrical contact with only one of the first electrical contacts, each first electrical contact being connected to a single corresponding one of the traces or interconnects that is different from a corresponding trace or interconnect connected to at least one other first electrical contact; and
a drive circuit connected to the first and second electrical contacts by the electrical traces or interconnects, the drive circuit being structured and connected so as to provide electrical drive current that flows through the array and causes the array to emit light, and that is further structured and connected so that (i) corresponding portions of the electrical drive current flow through one or more of the corresponding first electrical contacts as corresponding pixel currents, and (ii) at least one of the pixel currents is modulated so as to encode transmitted data, resulting in light emitted by the corresponding LEDs being modulated to encode the transmitted data.

15. A method for using the light-emitting array of claim 14, the method comprising:
(A) operating the drive circuit to provide one or more pixel currents to one or more of the corresponding first electrical contacts, causing the array to emit light; and
(B) while operating the drive circuit according to part (A), operating the drive circuit to provide a modulated pixel current to one or more of the LEDs, the modulated pixel current being modulated to encode transmitted data, so that light emitted by the array includes at least a portion that is modulated to encode the transmitted data.

16. The light-emitting array of claim 14, the drive circuit being further structured and connected so that each pixel current magnitude differs from the corresponding pixel current magnitude of at least one other of the LEDs of the array, the array being arranged as a display.

17. A method for using the light-emitting array of claim 16, the method comprising:
(A) operating the drive circuit to provide a first specified spatial distribution of pixel current magnitudes to the LEDs of the array, causing the array to emit light according to a corresponding first spatial distribution of light emission intensity across the array;
(B) operating the drive circuit to provide a second, different specified spatial distribution of pixel current magnitudes, causing the array to emit light according to a corresponding second spatial distribution of light emission intensity across the array that differs from the first spatial distribution of light emission intensity; and
(C) while operating the drive circuit according to one or both of parts (A) or (B), operating the drive circuit to provide a modulated pixel current to one or more of the LEDs, the modulated pixel current being modulated to encode transmitted data, so that light emitted by the array includes at least a portion that is modulated to encode the transmitted data.

18. A method for making a light-emitting array, the method comprising:
(A) forming, on a layer of n-doped GaN, an active layer comprising a III-nitride compound, the active layer being between 0.1 nm thick and 1 nm thick;
(B) forming, on the active layer, a layer of p-doped GaN, so that the n-doped GaN layer, the p-doped GaN layer, and the active layer therebetween form a light-emitting diode structure; and
(C) dividing at least the active layer and the p-doped GaN layer into discrete areal regions to form corresponding discrete light-emitting diodes (LEDs) of the array, each LED being arranged for emitting light at a nominal emission vacuum wavelength λ₀ resulting from charge carrier recombination at the active layer, each LED exhibiting a small-signal bandwidth greater than 0.10 GHz.

19. The method of claim 18 further comprising forming the active layer with an areal density of indium varying with position along the active layer of each LED.

20. The method of claim 18 further comprising forming the active layer as a monolayer of the III-nitride compound.
